(19) United States
(12) Patent Application Publication
(10) Pub. No.: US 2025/0253186 A1
(43) Pub. Date: Aug. 7, 2025

(54) SEMICONDUCTOR STRUCTURES AND MANUFACTURING METHOD OF THE SAME

(71) Applicant: Taiwan Semiconductor Manufacturing Company, Ltd., Hsinchu (TW)

(72) Inventors: Sheng Chieh Chuang, Hsinchu (TW); Wei-Lin Chang, Changhua City (TW)

(73) Assignee: Taiwan Semiconductor Manufacturing Company, Ltd., Hsinchu (TW)

(21) Appl. No.: 18/432,058

(22) Filed: Feb. 5, 2024

(51) Int. Cl. H01L 21/762; H01L 21/308

(52) U.S. Cl. CPC H01L 21/76224; H01L 21/308

(57) ABSTRACT

A semiconductor wafer and manufacturing methods thereof are described. The semiconductor wafer includes a semiconductor substrate, and an isolation structure. The isolation structure is embedded in the semiconductor substrate. The semiconductor substrate includes semiconductor segments. The semiconductor segments are spaced apart from each other by the isolation structure. The semiconductor segment includes a main portion and auxiliary portions on distal corners of the main portion. A number of the auxiliary portions is less than a number of the distal corners of the main portion.

### BACKGROUND

The electronics industry has experienced an increasing demand for smaller and faster electronic devices that are simultaneously able to support a greater number of increasingly complex and sophisticated functions. In order to meet these demands, there is a continuing trend in the integrated circuit (IC) industry to improve the integration density of various semiconductor devices and/or electronic components. This can be achieved by reducing IC dimensions (for example, by reducing minimum IC feature size), thereby allowing different types of components of various functions to be integrated into a given area. However, such scaling has also increased complexity of IC manufacturing processes. For example, as IC technologies are continually progressing to smaller technology nodes, scaling down larger nodes tend to result in inaccurate or poorly shaped device feature. Rounded corners on a device feature that are designed to have right-angle corners may be more pronounced in smaller nodes, thereby adversely affecting the device performance, quality and reliability. Typically, photolithography enhancement techniques, such as optical proximity correction (OPC) may be performed to alleviate these defects. However, patterning corner rounding is still an issue in various existing methods. Thus, there is a need for a method for IC design and mask fabrication to efficiently and significantly reduce patterning corner rounding, in order to produce integrated circuits with greater performance and reliability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A though FIG. 1I are schematic cross-sectional views illustrating structures produced at various stages of a semiconductor wafer fabrication method, in portion or entity, including patterning a semiconductor substrate by using a mask, according to some embodiments of the present disclosure.

FIG. 2A is a schematic plane view illustrating a mesh-shaped isolation structure formed on a semiconductor substrate, and FIG. 2B is a schematically enlarged plane view showing a region of the mesh-shaped isolation structure of FIG. 2A, according to some embodiments of the present disclosure.

FIG. 3A is a schematic plane view illustrating a portion of a lithography mask showing a grid of four semiconductors segments and an isolation structure, formed on a semiconductor substrate; and FIG. 3B is a schematic cross-sectional view of the grid of semiconductor segments and the isolation structure of FIG. 3A, illustrating a trench isolation structure, according to some embodiments of the present disclosure.

FIG. 4 is a schematic plane view illustrating a portion of a lithography mask showing four main features, and assist patterns formed in a space between distal corners of the main features, according to some embodiments of the present disclosure.

FIG. 5A, FIG. 5B through FIG. 8 are schematic plane views illustrating a portion of a lithography mask as examples of possible configurations of the main features and shapes of the main features and assist patterns, according to some embodiments of the present disclosure.

FIG. 9 is a schematic plane view illustrating an exemplary orientation of the assist patterns on distal corners, along the side lengths of a main feature.

FIG. 10 is a schematic plane view illustrating a portion of a lithography mask showing a group of assist patterns arranged in a diagonal line on the distal corners of a grid of main features aligned along a linear vertical line.

FIG. 11A and FIG. 11B are schematic plane views illustrating a portion of a lithography mask showing a group of assist patterns arranged along a vertical or horizontal linear axis of a grid of main features.

### DETAILED DESCRIPTION

The present disclosure relates generally to a semiconductor wafer and method of fabricating the semiconductor wafer, and a lithography mask for use in the fabrication of the semiconductor wafer.

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

In some embodiments, the manufacturing method is part of a wafer fabrication process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

A lithography mask including assist patterns and a method of using the lithography mask in semiconductor wafer fabrication to enhance critical dimension of an integrated circuit and minimize loading effect for application in image sensors with small pixels, are provided according to various embodiments. Throughout the various views and illustrative embodiments, like reference numbers are used to designate like elements.

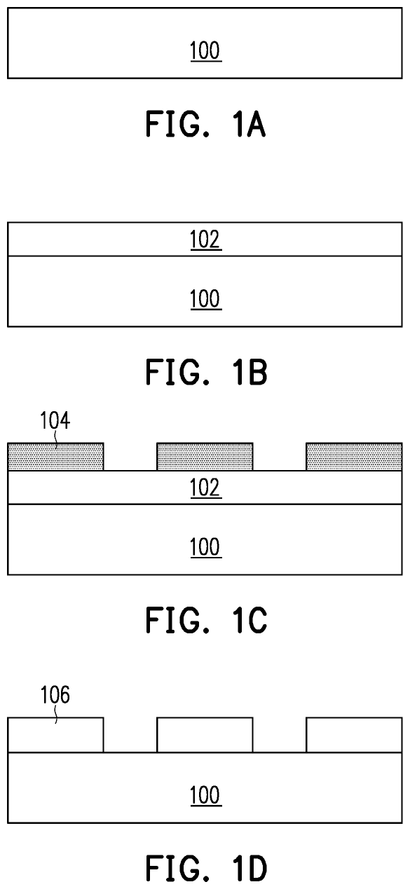

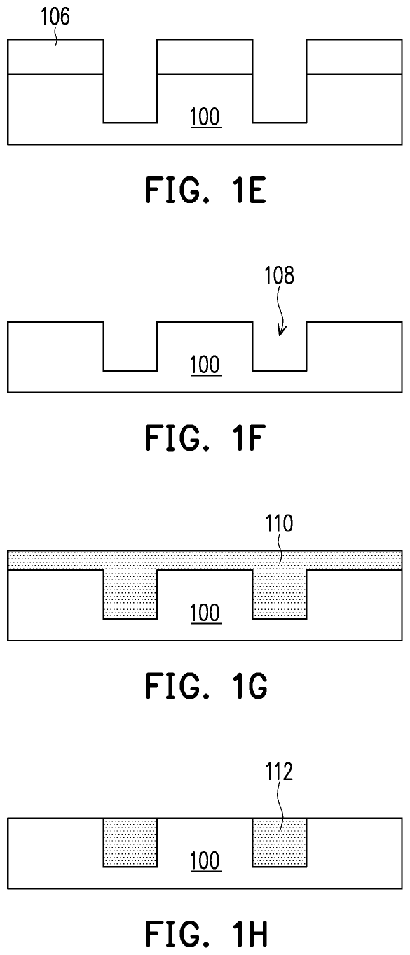

FIG. 1A through FIG. 1I are schematic cross-sectional views illustrating structures produced at various stages of a semiconductor wafer fabrication method, in portion or entity, including patterning a semiconductor substrate 100 according to some embodiments of the present disclosure. The method may be implemented, in whole or in part, by a system employing deep ultraviolet (DUV) lithography, electron beam (e-beam) lithography, x-ray lithography, and other lithography processes. Additional operations can be provided before, during, and after the method, and some operations described can be replaced, eliminated, or moved around for additional embodiments of the method.

Referring to FIG. 1A, the method for fabricating a semiconductor wafer includes the step of providing a semiconductor substrate 100. In some embodiment, the semiconductor substrate 100 is a silicon wafer. In some embodiments, the semiconductor substrate 100 is a bulk mono-crystalline silicon substrate, a layer of silicon on a silicon wafer, a layer of a silicon-on-insulator (SOI) wafer, or a layer of a germanium-on-insulator (GeOI) wafer. In other embodiments, other semiconductors, such as silicon germanium, germanium, gallium arsenide, indium arsenide, indium gallium arsenide, indium antimonide or others, can be used with the wafer.

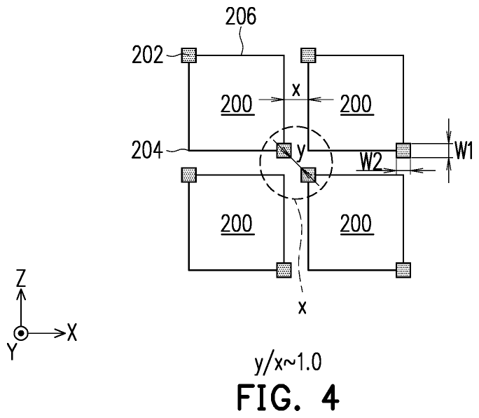

Referring to FIG. 1B, the method further includes providing a photo resist 102 on a top surface of the semiconductor substrate 100. In some embodiment, the method includes fabricating a lithography mask 104 using design (layout) data or lithography mask data, and providing the lithography mask 104 on the photo resist 102. Referring to FIG. 1C and FIG. 1D, the method further includes performing a photolithography process using the lithography mask 104, and developing the exposed photo resist 102, to transfer the patterns on the lithography mask onto the photo resist 102 such that a patterned photo resist 106 is formed on the semiconductor substrate 100. In an embodiment, as illustrated in FIG. 4, the lithography mask 104 includes main features 200 including side lengths 206, each of the side lengths 206 is spanned between distal corners 204 of the main features 200; and assist patterns 202 are formed on the distal corners 204 of the main feature 200, wherein a number of the assist patterns 202 is less than a number of the distal corners 204, however, the disclosure is not specifically limited thereto.

In some embodiment, as illustrated in FIG. 1E, the semiconductor wafer fabrication method includes performing an etching process to etch the semiconductor substrate 100 using the patterned photo resist 106, resulting from the development of the photo resist 102, as an etch mask. After the etching process, as illustrated in FIG. 1F, the patterned photo resist 106 may be removed by wet stripping or plasma removal to form trenches 108 in the semiconductor substrate 100. Referring to FIG. 1G and FIG. 1H, the method further includes, filling an isolating material 110 in the trenches 108; and performing a chemical mechanical polishing (CMP) process to form isolation structures 112 on the semiconductor substrate 100, thereby defining active regions surrounded by the isolation structures 112. The CMP process removes the excessive isolating material 110 and planarizes the top surface of the semiconductor substrate 100, wherein the isolating material 110 approximately flushes with the top surface of the semiconductor substrate 100. In some embodiments, the isolating materials 110 may be a single material or multiple materials. Examples of isolating materials 110 includes oxides, such as thermal oxide, High Density Plasma (HDP) oxide, High Aspect Ratio Process (HARP) formed oxide, Tetraethoxysilane (TEOS) formed oxides and various nitrides.

In some embodiments, as illustrated in FIG. 1I, the method further includes forming semiconductor devices 114 in the semiconductor substrate 100 after filling the isolating material 110 into the trenches 108. Each of the semiconductor devices 114 may be an intermediate device fabricated during processing of an IC, or a portion thereof, that may comprise resistors, capacitors, inductors, diodes, field-effect transistors (FETs), p-type FETs (PFETs), n-type FETs (NFETS), fin-like FETS (FinFETs), other three-dimensional (3D) FETs, metal-oxide-semiconductor FETs (MOSFET), complementary MOSFETs (CMOS), bipolar transistors, high voltage transistors, high frequency transistors, other memory cells, and combination thereof.

In some embodiments, the method further includes forming doped regions, dielectric features, and multi-layered interconnect structure 116 on the semiconductor substrate 100 and the isolation structures 112, at subsequently performed manufacturing steps. The interconnect structure 116 may include interconnect wirings, for example, copper wirings; and may provide electrical connection to the semiconductor devices 114 formed in the semiconductor substrate 100.

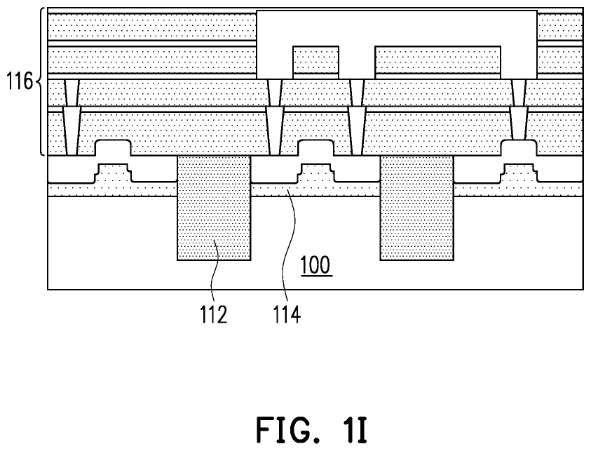

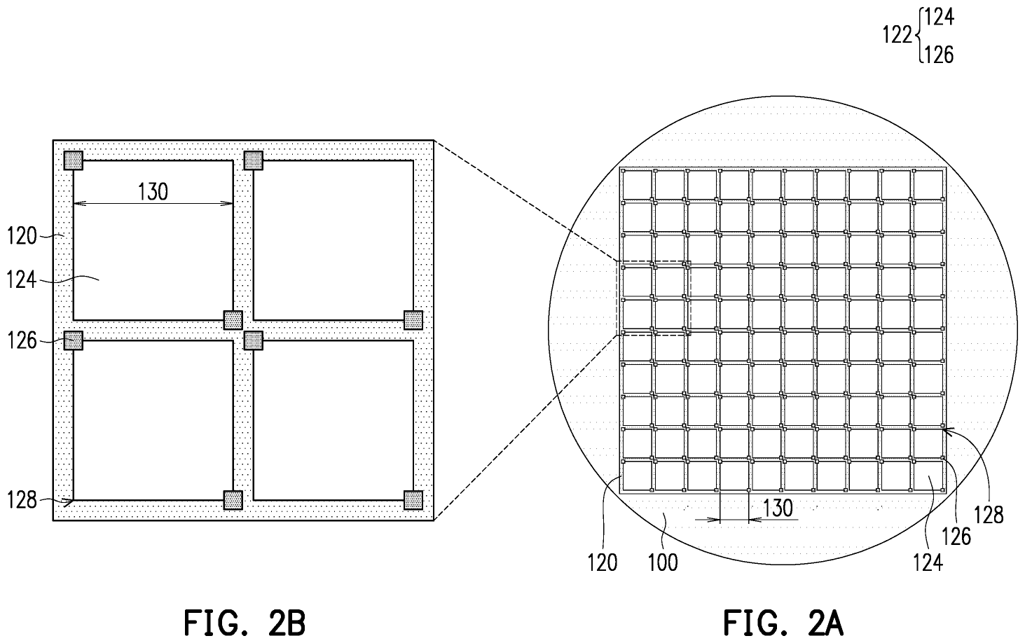

FIG. 2A is a schematic plane view illustrating a mesh-shaped isolation structure 120 formed on a semiconductor substrate 100, and FIG. 2B is a schematically enlarged, plane view showing a region of a semiconductor substrate 100 at a predetermined location of the semiconductor substrate 100 of FIG. 2A, which is outlined by a dashed-box depicted in FIG. 2A.

FIG. 2A depicts a mesh-shaped isolation structure 120 formed on a semiconductor substrate 100, and semiconductor segments 122 formed on the semiconductor substrate 100, wherein the semiconductor segments 122 are spaced apart from each other by the mesh-shaped isolation structure 120. In an embodiment, the semiconductor substrate 100 includes a plurality of semiconductor segments 122, wherein each of the semiconductor segments 122 incudes a main portion 124 and auxiliary portions 126. In some embodiment, the semiconductor segments 122 are arranged in an array, and are relatively symmetrical and spaced substantially equidistant from each other, however, the disclosure is not specifically limited thereto. In another embodiment, the semiconductor segments 122 may be spaced at different distances, or non-equidistant on the semiconductor substrate 100. The number of semiconductor segments 122 on the semiconductor substrate 100, as illustrated in FIG. 2A is of exemplary nature only. In other embodiments, an array of semiconductor segments 122 included on the semiconductor substrate 100 different from an area shown in FIG. 2A, may be provided. In some embodiments, the auxiliary portions 126 are positioned on distal corners 128 of the main portion 124, wherein a number of the auxiliary portions 126 is less than a number of the distal corners 128 of the main portion 124. In some embodiments, the semiconductors segments 122, includes at least two auxiliary portions 126 which are unconnected to each other along a same side length 130 of a main portion 124. The auxiliary portions 126 are positioned on the distal corners 128 of the main portions 124 of the semiconductor segments 122 to compensate for the pattern distortion, caused by optical diffraction, resist development, etch, and other undesirable effects that occur during the lithography process, between the original mask pattern, that is, the design, and the final transferred circuit pattern on the semiconductor substrate 100. The auxiliary portions 126 interact with the main portions 124 of the semiconductor segment 122, and with each other and compensate for proximity effects to improve the final transferred circuit pattern. In some embodiments, the auxiliary portions 126 added to improve pattern transference is referred to as “serifs”. Serifs are small features that can be positioned on a distal corner 128 of a main portion 124 of a semiconductor segment 122 to sharpen the distal corners 128 of the semiconductor segments 122, in the final transferred image. In some embodiments, the main portion 124 of the semiconductor segment 122 may be resized, repositioned, and/or reshaped, when the auxiliary portions 126 are added. In an alternative embodiment, various auxiliary features, such as scattering bars, serifs or hammerheads may be added to the main portions 124 of the semiconductor segments 122. The auxiliary features may be placed a distance away from the main portions 124 (such as scattering bars) or be placed adjacent to the main portions 124 (such as serifs and hammerheads). In some embodiment, a serif feature is added to the distal corners 128 of the main portions 124 of the semiconductor segments 122.

In some embodiments, the auxiliary portions 126 may be added to the main portions 124 of the semiconductor segments 122 by performing an optical proximity correction (OPC) to an IC design layout. The OPC is performed to correct the image errors by modifying the IC design layout. The OPC process may be model-based, rule-based OPC, table-based OPC, or combinations thereof. In some embodiment, in the case of rule-based OPC, correction rules are determined ahead of time, which specify how different semiconductor segments 122 should be modified according to some simple measures associated with the shapes being considered, for example, feature width and spacing of semiconductor segments 122. In some embodiments, rule-based OPC includes serif, that will be applied to distal corners 128 of the semiconductor segments 122, to correct for corner rounding, and line edge displacement.

In some embodiments, the corrections comprise applying individual auxiliary portions 126 (i.e., serif) to alternating side lengths 130 or distal corners 128 of the semiconductor segments 122. In some embodiments, the corrections comprise applying individual auxiliary portions 126 (i.e., serif) to two or three consecutive side lengths 130 or distal corners 128 of the semiconductor segments 122. In some embodiments, the auxiliary portions 126 (i.e., serif) may be applied to any side lengths 130 or distal corners 128 of the semiconductor segments 122.

FIG. 2B is a schematically enlarged, plane view showing a region of a semiconductor substrate 100 at a predetermined location of the semiconductor substrate 100 of FIG. 2A. As illustrated in FIG. 2B, the semiconductor substrate 100 includes a mesh-shaped isolation structure 120 embedded in the semiconductor substrate 100, and semiconductor segments 122 are spaced apart from each other by the mesh-shaped isolation structure 120. Each of the semiconductor segments 122 includes a main portion 124, and auxiliary portions 126 positioned on distal corners 128 of the main portion 124. In an embodiment, the main portion 124 includes 4 side lengths 130, 4 distal corners 128, and a number of the auxiliary portions 126 is two, however, the disclosure is not specifically limited thereto. In another embodiment, four neighboring semiconductor segments 122 among the semiconductor segments 122 are arranged adjacent to each other, and the four neighboring semiconductor segments 122 are spaced apart from each other by a cross-shaped isolation pattern of the mesh-shaped isolation structure 120.

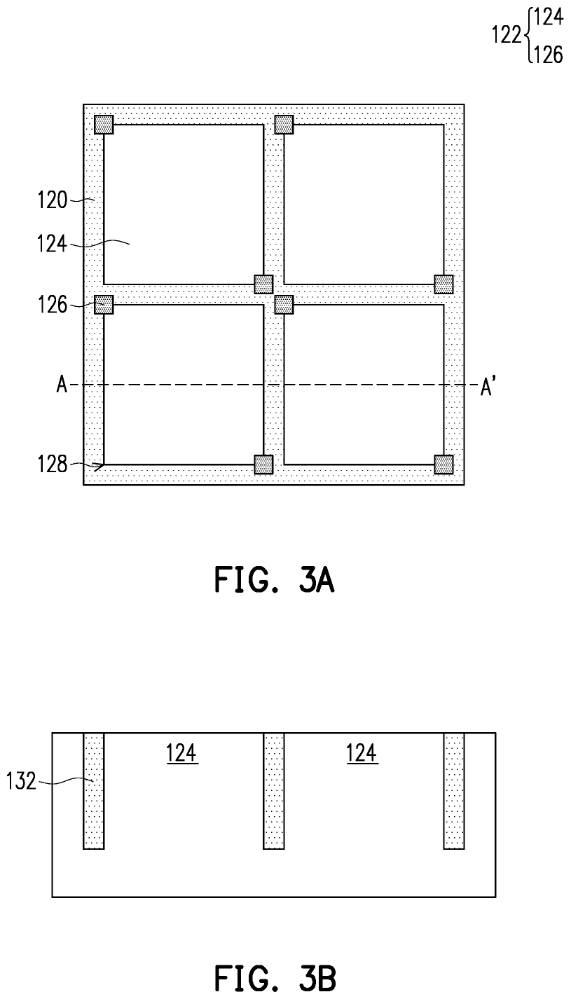

FIG. 3A is a schematic plane view illustrating a portion of a lithography mask showing a grid of four semiconductors segments 122 and an isolation structure 120, formed on a semiconductor substrate 100, according to some embodiments of the present disclosure. FIG. 3B is a schematic cross-sectional view illustrating a trench isolation structure 132, according to some embodiments of the present disclosure, where the cross-sectional view is taken along a line A-A′ depicted in the plane view of FIG. 3A. In an embodiment, each of the trench isolation structure 132 includes a bottom portion and first and second trench sidewalls. The trench isolation structures 132 may be filled with an isolating material 110, for example, oxides, and various nitrides; and is planarized to at least the level of the top surface of the semiconductor substrate 100 (as illustrated in FIG. 1). Additional processes may be performed to form an IC structure that includes active semiconductor regions separated by the trench isolation structure 132.

FIG. 4 is a schematic plane view illustrating a portion of a lithography mask having an exemplary grid of main features 200. In some embodiment, as illustrated in FIG. 4, the main features 200 of the lithography mask is depicted as a square, and assist patterns 202 are positioned in a space x between distal corners 204 of the main features 200. Each of the square main features 200 having four side lengths 206 along its perimeter boundary, and are spaced about 10 to 300 nm from each other, as indicated by a distance x. In some embodiment, the square main feature 200 has a distal corner 204 that approximately faces a distal corner 204 of another square main feature 200 in a space x. Assist patterns 202 are applied on the two distal corners 204 of the main features 200, in the space x. In some embodiments, a design rule to determine the minimum distance between main features 200 may be used. The minimum distance is applied to the distances between main features 200, the distances between assist patterns 202 and the distances between main features 200 and assist patterns 202. The assist patterns 202 as illustrated in FIG. 4 may be modified to accommodate the minimum distance required. The appropriate minimum distance for any particular application will depend on the particular wafer, photolithography process and equipment. In some embodiments, the outer contour or boundaries of the main features 200 are modified by an assist pattern 202 formed on the distal corners 204 of the main features 200. In some embodiments, the assist patterns 202 are positioned on the distal corners 204 of the main features 200, and a portion of the assist patterns 202 overlap with the distal corners 204 of the main feature 200. In some embodiment, the assist patterns 202 having a width W1, and a length W2, is added to the main feature 200. In some embodiments, the width W1 and the length W2 of the assist patterns 202 may be independently of each other, in the range between 5 nm to 150 nm, but the disclosure is not limited thereto. The width W1 and the length W2 of the assist patterns 202 may be adjusted according to design or performance requirements.

The specific arrangement of the assist patterns 202 within the space x results in the contour edges of the main features 200 having more defined locations, to compensate for influence exerted by the assist patterns 200 applied to the nearby main features 200. Consequently, bridging risks are mitigated, and cross-road loading effect can be significantly minimized, thereby enhancing the critical dimension of a photomask. In some embodiment, the ratio of the distance x between the adjacent main features 200 that are the spaced from each other along the x-direction, may be equidistant to the distance y, between the assist patterns 202 formed on the distal corners 204 of adjacent main features 200. In some embodiment, the ratio of distance y to distance x is approximately equals to one (y/x˜1.0). In some embodiment, the main features 200 exhibited a cross-road loading effect of less than 20%, wherein the loading effect is defined as the difference in spatial distance between the 2D features and 1D features, divided by the distance between the 1D features. The 1D features are depicted by the side lengths 206 of the main features 200, and 2D features are depicted by the assist patterns 202 on adjacent main features 200, wherein the assist patterns are positioned diagonally opposite each other on the main features 200, within space x.

As illustrated in FIG. 4, each of the main features 200 has an assist pattern 202 added to alternating distal corners 204 of the main feature 200, to provide extra area in an attempt to reduce optical and processing effects that reduce the sharpness of the distal corners 204.

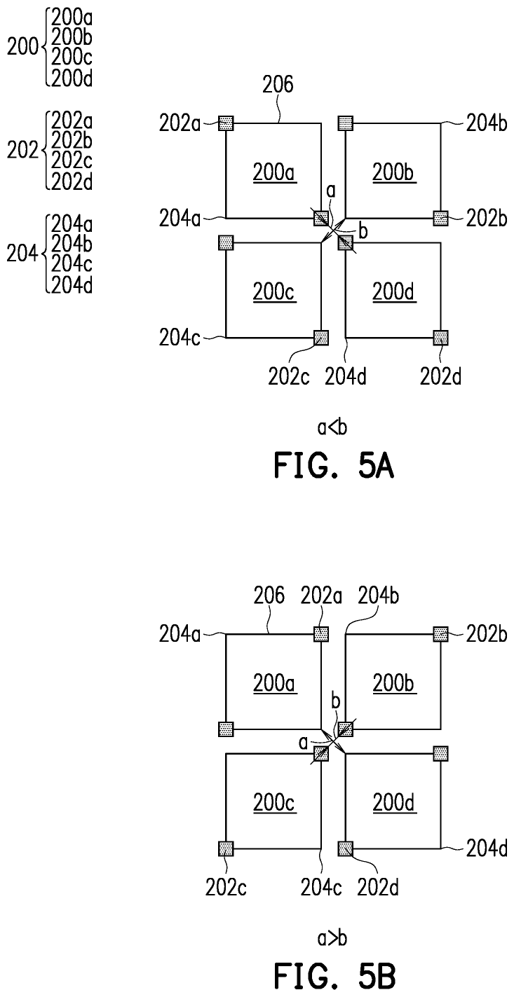

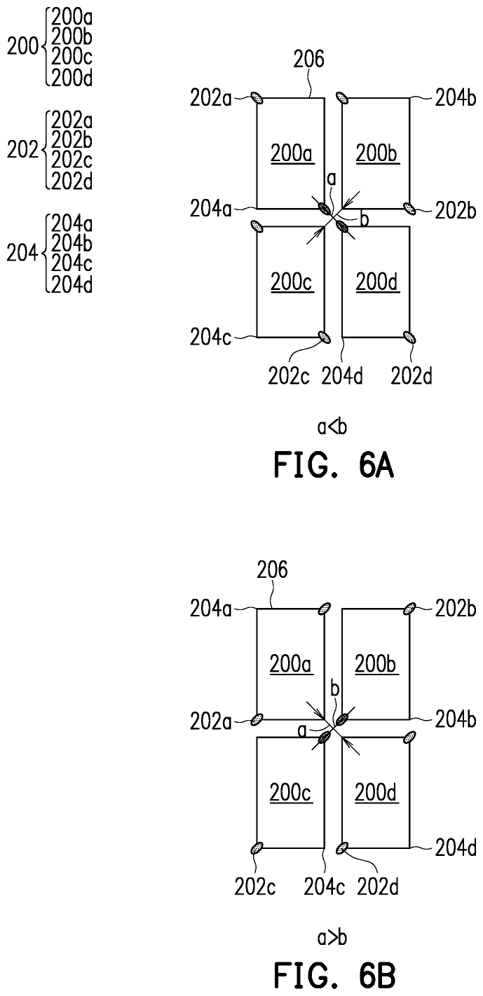

FIG. 5A, FIG. 5B through FIG. 8 are schematic plane views illustrating a portion of a lithography mask as examples of possible configurations of the main features 200 and shapes of the main features 200 and assist patterns 202, according to some embodiments of the present disclosure. In some embodiment, the main feature 200 has a symmetric geometry. In other embodiments, the main feature 200 may have other geometries, sizes, and may be symmetrical or asymmetrical. For example, the main feature 200 may be a square, a rectangle, a rhombus, a hexagon, or other suitable shapes. In other embodiments, main features 200 with distal corners 204 includes other types of quadrangles, parallelograms and other types of polygons may be used. In another embodiment, main features 200 that do not have well-defined corners, such as curved shapes, may also be included. The lithography mask uses a plurality of assist patterns 202 of all sizes and polarities. In some embodiments, the shape of the assist patterns 202 are determined by a resolution limit of an optical exposure tool used during a mask fabrication process. In some embodiment, the assist pattern may have a symmetrical cross-sectional profile, for example, a square-shaped, a rectangular-shaped, a spherical shape, an ellipse-shaped cross-sectional profile, however, the disclosure is not specifically limited thereto. The assist patterns 202 are positioned on the distal corners 204 of the main features 200 such that a portion of surface area for each of the assist patterns 202 overlaps the corner regions of the main feature 200. In some embodiment, approximately 0 to 25 percent of the total surface area of the assist patterns 202 overlap the distal corners 204 of the lithography mask. The positions and dimensions (i.e., size, width, length) of the assist patterns 202 may be carefully adjusted based on the shapes, sizes and local proximity of neighboring main features 200. The adjustment may be achieved by simulation and experimentation. The optimal position and dimension of the assist patterns 202 may be determined based on several requirements. For example, assist patterns 202 may be selected to be large enough to improve the process window of the main feature 200; without significantly increasing the mask error enhancement factor of the main features 200 or go beyond the resolution limits of the mask manufacturing process. Additional requirements and design rules may be taken into consideration depending on the particular application. While the illustrations all show assist patterns 202 of one consistent width within the same main feature 200. It should be noted that a consistent width is not necessary. The width of the assist patterns 202 may be varied depending on the application. The sizes of the assist patterns may be optimized through OPC, through experimentation or other ways. The optimal position and dimensions of the assist patterns 202 may be determined empirically, by exposing the test wafers with main features 200 of different sizes and shapes, and applying different number and different sized assist patterns on the distal corners 202 of the main features 200, and then examining the results.

As illustrated in FIG. 5A, FIG. 5B through FIG. 8, the main feature 200 of the lithography mask is depicted as a polygon. Each of the polygonal main feature 200 includes a plurality of side lengths 206, each of the side lengths 206 is spanned between distal corners 204 of the polygonal main features 200. The polygonal main features 200 further include a plurality of assist patterns 202 formed on the distal corners 204 of the polygonal main features 200, wherein a number of the assist patterns 202 is less than a number of the distal corners 204 of the polygonal main features 200. In some embodiment, the assist patterns 202 formed on the distal corners 204 of the polygonal main feature 200 may be spaced apart from its neighboring assist pattern 202 by at least one distal corner 204 along a perimeter boundary of the polygonal main feature 200.

In some embodiment, the polygonal main feature 200 may be a four-sided polygon (i.e., quadrilateral). In some embodiment, the quadrilateral may be equilateral, for example, a square or a rhombus. In another embodiment, the quadrilateral may not be equilateral, for example, a rectangle. In some embodiment, the quadrilateral may be equiangular, for example, a square or a rectangle. In another embodiment, the quadrilateral may not be equiangular, for example, a rhombus. In an alternative embodiment, the polygonal main feature 200 may be a six-sided polygon (i.e., hexagon). In some embodiment, the hexagon may or may not be equilateral and equiangular.

In some embodiment, as illustrated in FIG. 5A and FIG. 6A, the assist patterns 202a, 202d are formed on distal corners 204a, 204d of the main features 200a, 200d. The assist pattern 202a on main feature 200a is diagonally opposite to a neighboring assist pattern 202d on main feature 200d. In some embodiment, as illustrated in FIG. 5B and FIG. 6B, the assist patterns 202b, 202c are formed on distal corners 204b, 204c of the main features 200b, 200c. The assist pattern 202b on main feature 200b is diagonally opposite to a neighboring assist pattern 202c on main feature 200c. In another embodiment, as illustrated in FIG. 7A, the assist pattern 202a on main feature 200a is linearly opposite a neighboring assist pattern 202d on main feature 200d along a vertical axis (in the y-direction). In an alternative embodiment, as illustrated in FIG. 7B, the assist pattern 202b on main feature 200b is linearly opposite a neighboring assist pattern 202c on main feature 200c along a horizontal axis (in the x-direction).

Referring to FIG. 5A, FIG. 6A and FIG. 7A, the assist pattern 202a on main feature 200a is separated by a distance a from assist pattern 202d on main feature 200d. The distal corners 204b, 204c on main features 200b, 200c, intersecting with the assist patterns 202a, 202d are separated by a distance b, wherein assist patterns 202a, 202d and distal corners 204b, 204c are located within a space defined by main features 200a, 200b, 200c, 200d. In some embodiment, distance a and distance b are different. In an embodiment, distance a may be smaller than distance b. Referring to FIG. 5B, FIG. 6B and FIG. 7B, the assist pattern 202b on main feature 200b is separated by a distance b from assist pattern 202c on main feature 200c. The distal corners 204a, 204d on main features 200a, 200d, intersecting with the assist patterns 202b, 202c are separated by a distance a, wherein assist patterns 202b, 202c and distal corners 204a, 204d are located within a space defined by main features 200a, 200b, 200c, 200d. In some embodiment, distance a and distance b are different. In an embodiment, distance a may be larger than distance b.

Referring to FIG. 8, the assist pattern 202a on main feature 200a is separated by a distance a from distal corners 204b, 204c on adjacent main features 200b, 200c. The distal corners 204b, 204c on main features 200b, 200c are separated by a distance b, wherein assist patterns 202a and distal corners 204b, 204c are located within a space defined by adjacent main features 200a, 200b, 200c. In some embodiment, distance a may be smaller than distance b. The embodiments of the present disclosure may be applied to many other types and shapes of features and to structures that are simpler and more complex than those shown.

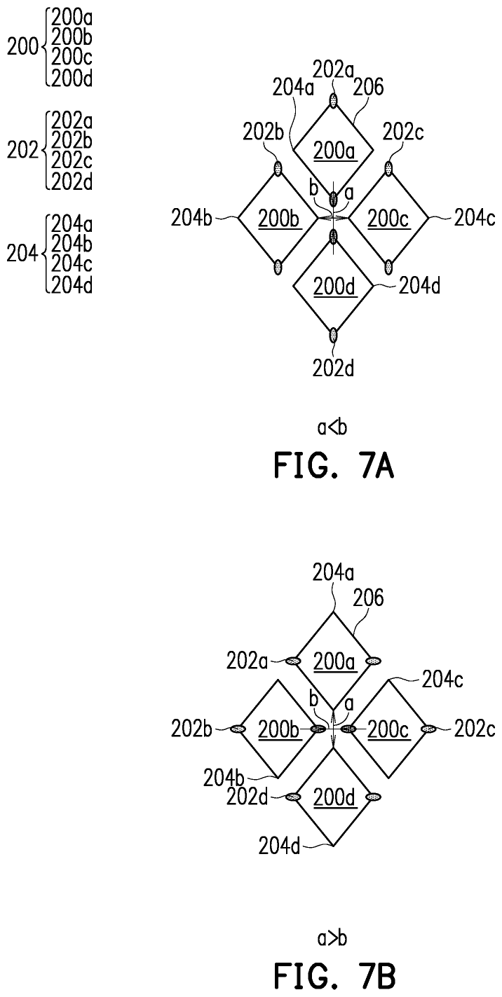

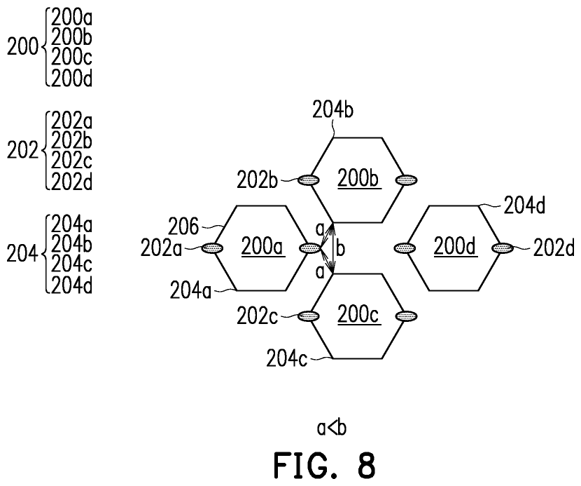

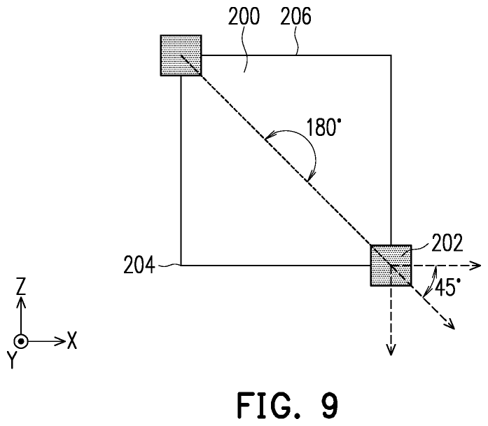

FIG. 9 is a schematic plane view illustrating an exemplary orientation of the assist patterns 202 on the distal corners 204, along the side lengths 206 of a main feature 200. As illustrated in FIG. 9, a first assist pattern 202 and a second assist pattern 202 are spaced apart from each other by a straight angle (180-degree angle). In some embodiment, the assist patterns 202 are applied along a diagonal axis. Each axis passes through the center of at least one main feature 200 and the line is at forty-five degree angle to the vertical (in y-direction) and horizontal (in x-direction) linear axes of the main features 200.

FIG. 10 a schematic plane view illustrating a portion of a lithography mask showing a group of assist patterns 202 arranged in a diagonal line B-B′ on the distal corners 204 of a grid of main features 200 aligned along a linear vertical line (in y-direction). In an embodiment, the main features 200 are aligned along three rows. There are three main features 200 in each of the rows, thereby forming a grid of nine main features 200. In some embodiments, the assist patterns 202 extend from two of the four distal corners 204 of each of the nine square main features 200. In some embodiments, the assist patterns 202 may be formed on alternating distal corners 204 of each of the square main features 200, thereby resulting in the assist pattern 202 to be spaced apart from its nearest neighboring assist pattern 202 on each of the square main features 200 by a straight angle (180-degree angle) (as depicted in FIG. 9). As illustrated in FIG. 10, each of the square main features 200 has assist patterns 202 extending diagonally from two of its four distal corners 204, wherein the assist patterns 202 are formed on distal corners 204 of different side lengths 206 along the contour of the main feature 200, and the assist patterns 202 are formed diagonally opposite each other in each main feature 200. In some other embodiments, a center point of the assist pattern 202 extending from the distal corners 204 of the main features 200 may be approximately 0 to 90-degree angle from the vertical linear axis C-C′ of the main features 200 (in y-direction). In an embodiment, as illustrated in FIG. 10, a center point of the assist pattern 202 extending from the distal corners 204 of the main features 200 may be formed at 45 degree angle from the vertical linear axis C-C′ of the main features 200 (in y-direction). In some embodiments, a different array may also be applied to the same and different configurations of main features 200. More or less assist patterns 202 in each direction may be used. The dimensions (i.e., length, width, thickness) of the assist patterns 202 throughout the grid of main features 200 may be adjusted based on modeling and experimentation.

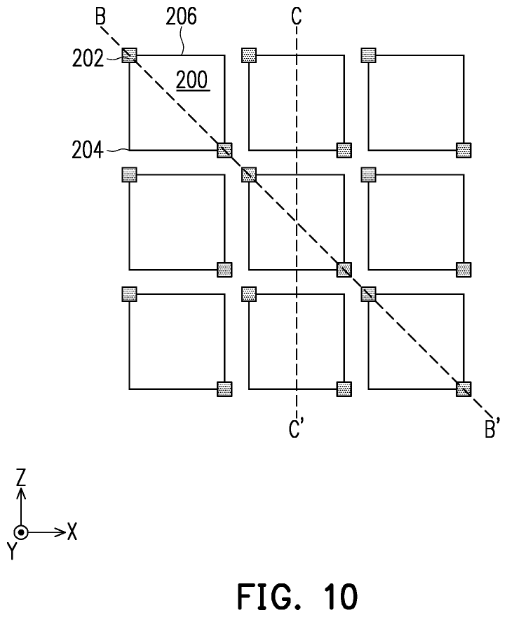

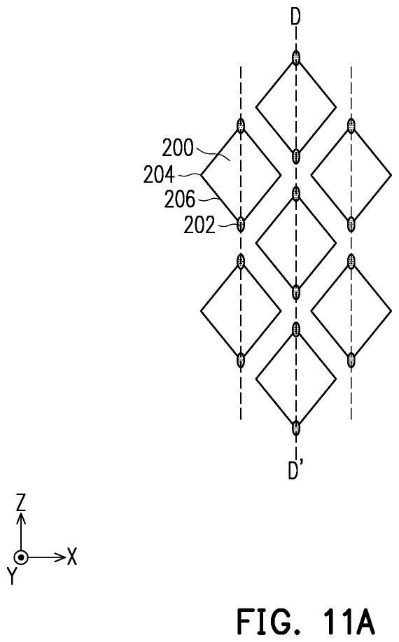

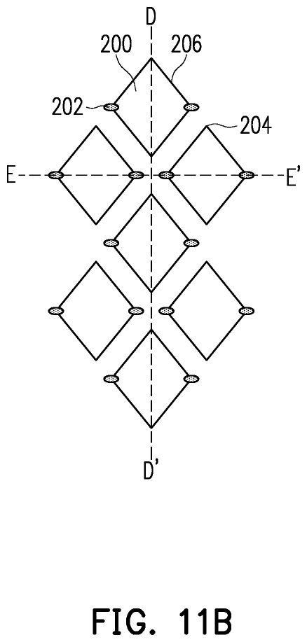

FIG. 11A and FIG. 11B are schematic plane views illustrating a portion of a lithography mask showing a group of assist patterns 202 arranged along a vertical linear axis D-D′ (in y-direction), or horizontal linear axis E-E′ (in x-direction), of a grid of main features 200. In an embodiment, a regular group of assist patterns 202 extends from the distal corners 204 of the main features 200 in the form of a vertical straight segment, as illustrated in FIG. 11A, or a horizontal straight segment, as illustrated in FIG. 11B. In some other embodiments, a center point of the assist pattern 202 extending from the distal corners of the main features may be approximately 0 to 90-degree angle from the vertical linear axis D-D′ of the main features 200 (in y-direction). In another embodiment, as illustrated in FIG. 11A, a center point of the assist pattern 202 extending from the distal corners 204 of the main features 200 may be formed at 0-degree angle from the vertical linear axis D-D′ of the main features 200 (in y-direction). In another embodiment, as illustrated in FIG. 11B, a center point of the assist pattern 202 extending from the distal corners 204 of the main features 200 may be formed at 90-degree angle from the vertical linear axis D-D′ of the main features 200 (in y-direction). Other angles may alternatively be used and it is not necessary that all of the assist patterns 202 be at the same angle to the grid of the main features 200. The assist patterns 202 may be placed at other angles, such as thirty, sixty or any other number of degrees from the grid of main features 200. The optimal angle may be selected upon the configuration of the main features 200 and the particular application.

In accordance with some embodiments of the disclosure, a semiconductor wafer including a semiconductor substrate, and an isolation structure is provided. The isolation structure is embedded in the semiconductor substrate. The semiconductor substrate includes semiconductor segments. The semiconductor segments are spaced apart from each other by the isolation structure. The semiconductor segment includes a main portion and auxiliary portions on distal corners of the main portion. A number of the auxiliary portions is less than a number of the distal corners of the main portion. In some embodiments, wherein the main portion comprises four distal corners, a number of the auxiliary portions is two. In some embodiments, wherein the main portion comprises six distal corners, a number of the auxiliary portions is two. In some embodiments, the isolation structure includes trench-isolation structure. In some embodiments, the isolation structure includes a meshed-shaped isolation structure. In some embodiments, the semiconductor wafer, wherein four neighboring semiconductor segments among the semiconductor segments are arranged adjacent to each other, the four neighboring semiconductor segments are spaced apart from each other by a cross-shaped isolation pattern of the meshed-shaped isolation structure. In some embodiments, the semiconductor wafer further includes an interconnect structure disposed on the semiconductor substrate. In some embodiments, the semiconductor wafer further includes semiconductor devices distributed in the semiconductor segments.

In accordance with some embodiments of the disclosure, a mask including main features and assist patterns is provided. The main features include side lengths, each of the side lengths is spanned between distal corners of the main features. The assist patterns are formed on the distal corners of the main features. A number of the assist patterns is less than a number of the distal corners. In some embodiments, each of the main features includes a polygon, selected from a group consisting of a square, a rectangle, a rhombus, and a hexagon. In some embodiments, the assist patterns have a symmetrical cross-sectional profile selected from the group consisting of a square-shaped, a rectangular-shaped, a spherical shaped, an ellipse-shaped cross-sectional profile. In some embodiments, a center point of the assist pattern extending from the distal corners of the main features at approximately 45-degree angle. In some embodiments, the assist patterns formed on the distal corners of the main features are arranged along a diagonal axis to the linear axis of the main features. In some embodiments, the assist patterns formed on the distal corners are spaced apart from its nearest neighboring assist pattern on each of the main features by a straight angle (180-degree angle). In some embodiments, the assist patterns formed on the distal corners of the main features are arranged along a vertical linear axis of the main features. In some embodiments, the assist patterns formed on the distal corners of the main features are arranged along a horizontal linear axis of the main features. In some embodiments, a distance between the assist patterns extending from the distal corners of the main features, is less than a distance between the distal corners of the main features intersecting with the assist patterns.

In accordance with some other embodiments of the disclosure, a method of fabricating a semiconductor wafer is provided. The method includes the following steps: patterning a semiconductor substrate by using a mask to form a trench in the semiconductor substrate, the mask comprising main features having side lengths, each of the side lengths is spanned between distal corners of the main features; and assist patterns formed on the distal corners of the main features, wherein a number of the assist patterns is less than a number of the distal corners, and filling a dielectric material into the trench to form an isolation structure. In some embodiments, the method further includes forming semiconductor devices in the semiconductor substrate after filling the dielectric material into the trench. In some embodiments, the method further includes forming an interconnect structure on the semiconductor substrate and the isolation structure.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor wafer, comprising:
a semiconductor substrate comprising semiconductor segments; and
an isolation structure embedded in the semiconductor substrate, the semiconductor segments being spaced apart from each other by the isolation structure, wherein at least one of the semiconductor segments comprises:
a main portion; and
auxiliary portions on distal corners of the main portion, wherein a number of the auxiliary portions is less than a number of the distal corners of the main portion.

2. The semiconductor wafer of claim 1, wherein the main portion comprises four distal corners, and a number of the auxiliary portions is two.

3. The semiconductor wafer of claim 1, wherein the main portion comprises six distal corners, and a number of the auxiliary portions is two.

4. The semiconductor wafer of claim 1, wherein the isolation structure comprises trench-isolation structure.

5. The semiconductor wafer of claim 1, wherein the isolation structure comprises a meshed-shaped isolation structure.

6. The semiconductor wafer of claim 5, wherein four neighboring semiconductor segments among the semiconductor segments are arranged adjacent to each other, and the four neighboring semiconductor segments are spaced apart from each other by a cross-shaped isolation pattern of the meshed-shaped isolation structure.

7. The semiconductor wafer of claim 1 further comprising:
an interconnect structure disposed on the semiconductor substrate.

8. The semiconductor wafer of claim 1 further comprising semiconductor devices distributed in the semiconductor segments.

9. A mask, comprising:
main features having side lengths, each of the side lengths is spanned between distal corners of the main features; and
assist patterns formed on the distal corners of the main features, wherein a number of the assist patterns is less than a number of the distal corners.

10. The mask of claim 9, wherein each of the main features comprising a polygon, selected from a group consisting of a square, a rectangle, a rhombus, and a hexagon.

11. The mask of claim 9, wherein the assist patterns have a symmetrical cross-sectional profile selected from the group consisting of a square-shaped, a rectangular-shaped, a spherical shaped, an ellipse-shaped cross-sectional profile.

12. The mask of claim 9, wherein a center point of the assist pattern extending from the distal corners of the main features at approximately 45-degree angle.

13. The mask of claim 9, wherein the assist patterns formed on the distal corners of the main features are arranged along a diagonal axis to the linear axis of the main features.

14. The mask of claim 9, wherein the assist patterns formed on the distal corners are spaced apart from its nearest neighboring assist pattern on each of the main features by a straight angle (180-degree angle).

15. The mask of claim 9, wherein the assist patterns formed on the distal corners of the main features are arranged along a vertical linear axis of the main features.

16. The mask of claim 9, wherein the assist patterns formed on the distal corners of the main features are arranged along a horizontal linear axis of the main features.

17. The mask of claim 9, wherein a distance between the assist patterns extending from the distal corners of the main features, is less than a distance between the distal corners of the main features intersecting with the assist patterns.

18. A method for fabricating a semiconductor wafer, comprising:
patterning a semiconductor substrate by using a mask to form a trench in the semiconductor substrate, the mask comprising main features having side lengths, each of the side lengths is spanned between distal corners of the main features; and assist patterns formed on the distal corners of the main features, wherein a number of the assist patterns is less than a number of the distal corners; and
filling a dielectric material into the trench to form an isolation structure.

19. The method of claim 18, further comprising forming semiconductor devices in the semiconductor substrate after filling the dielectric material into the trench.

20. The method of claim 18, further comprising forming an interconnect structure on the semiconductor substrate and the isolation structure.
